(19) United States
(12) Patent Application Publication
(10) Pub. No.: US 2006/0292784 A1
(43) Pub. Date: Dec. 28, 2006

(54) Methods of Forming Integrated Circuit Devices Including Memory Cell Gates and High Voltage Transistor Gates Using Plasma Re-Oxidation

(76) Inventors: Woong hee Sohn, Seoul (KR); Gil-heyun Choi, Gyeonggi-do (KR); Chang-won Lee, Gyeonggi-do (KR); Byung-hee Kim, Seoul (KR); Tae-ho Cha, Gyeonggi-do (KR)

Correspondence Address: MYERS BIGEL SIBLEY & SAJOVEC, PO BOX 37428, RALEIGH, NC, 27627, US

(21) Appl. No.: 11/424,995

(22) Filed: Jun. 19, 2006

(30) Foreign Application Priority Data
Jun. 23, 2005 (KR) 10-2005-0054566

(51) Int. Cl. H01L 21/8238

(52) U.S. Cl. 438/201

(57) ABSTRACT

A method of forming an integrated circuit device can include forming a plurality of stacked cell gates in a memory cell region of a semiconductor substrate and a plurality of high-voltage transistor gates in a peripheral circuit region of the semiconductor substrate. The semiconductor substrate including both the plurality of stacked cell gates and the plurality of high-voltage transistor gates is annealed and the annealed semiconductor substrate including both the plurality of stacked cell gates and the plurality of high-voltage transistor gates is plasma oxidized.

### CROSS-REFERENCE TO RELATED APPLICATION

This application claims priority from Korean Patent Application No. 10-2005-0054566, filed on Jun. 23, 2005, in the Korean Intellectual Property Office, the disclosure of which is incorporated herein in its entirety by reference.

### FIELD OF THE INVENTION

The present invention relates to methods of forming integrated circuit devices, and more particularly, to methods of integrated circuit devices including both memory cells and high-voltage transistors.

### BACKGROUND

To restore damages of an oxide layer, a gate sidewall, a substrate, etc. caused during a gate patterning process in the course of fabricating a semiconductor integrated circuit device, a reoxidation process is generally performed after the gate patterning process.

Recently, a metal gate or a silicide gate including a metal-containing layer, such as a metal or a metal silicide layer, is used in a stacked Gate structure. In a case of using the metal gate, the effective sectional area of the metal gate can be reduced due to surface oxidation of the metal layer during a reoxidation process, and thus gate line resistance may increase, thereby leading to increased delay in signal transmission and a poor vertical profile of the metal gate pattern. In view of these problems, a selective oxidation process using the partial pressure ratio of H₂O and H₂ has been used as a reoxidation process to prevent the oxidation of a metal layer and to compensate for damage caused by patterning. According to some conventional reoxidation processes, however, severe bird's beak encroachment may occur in a gate oxide layer, which may lead to punch-through phenomenon.

In some semiconductor integrated circuit devices including high-voltage transistors in a peripheral circuit region, together with memory cells, the active regions of the high-voltage transistors in the peripheral circuit region may have a range of threshold voltages developed due to a reoxidation process, which is sometimes called a “hump phenomenon”. The hump phenomenon is attributable to a predetermined off-state drain leakage current (Idoff) Generated even when no gate voltage is applied, and may reduce uniformity in cell distribution, which may adversely affect device reliability.

### SUMMARY

Embodiments according to the invention can provide methods of forming integrated circuit devices including memory cell gates and high voltage cell gates using plasma re-oxidation. Pursuant to these embodiments, a method of forming an integrated circuit device can include forming a plurality of stacked cell gates in a memory cell region of a semiconductor substrate and a plurality of high-voltage transistor gates in a peripheral circuit region of the semiconductor substrate. The semiconductor substrate including both the plurality of stacked cell gates and the plurality of high-voltage transistor gates is annealed and the annealed semiconductor substrate including both the plurality of stacked cell gates and the plurality of high-voltage transistor gates is plasma oxidized.

In some embodiments according to the invention, a method of forming an integrated circuit device, includes annealing a substrate including both a plurality of stacked cell gates and a plurality of high-voltage transistor gates and then oxidizing the annealed semiconductor substrate using a plasma including H₂ gas and O₂ gas provided at a flow rate ratio (H₂ to O₂) of about 0 to about 16. In some embodiments according to the invention, if the stacked cell gates include a first metal layer and the high-voltage transistor gates include a second metal layer, the flow rate ratio (H₂ to O₂) comprises about 0 to about 16. However, if the stacked cell gates include a first silicide layer and the high-voltage transistor gates include a second silicide layer the flow rate ratio (H₂ to O₂) comprises about 0.5 to about 16.

In some embodiments according to the invention, a method of forming an integrated circuit device includes annealing a substrate including both stacked cell gates of a memory and high-voltage transistor gates both including either metal or silicide containing layers and then re-oxidizing portions of the substrate having both the stacked cell gates and the high-voltage transistor gates in a plasma process including H₂ and O₂.

### BRIEF DESCRIPTION OF THE DRAWINGS

FIG. 1 is a flowchart diagram illustrating methods of forming semiconductor integrated circuit devices according to some embodiments of the present invention.

FIGS. 2A through 2C are sequential sectional views illustrating a method of manufacturing a semiconductor integrated circuit device according to an embodiment of the present invention.

FIG. 3 is a graph illustrating tunnel gate leakage evaluation results for stacked cell gates of semiconductor integrated circuit devices formed using a conventional selective oxidation process vs. a plasma oxidation process according to some embodiments of the present invention.

FIG. 4 is a graph illustrating off-state drain leakage current (Idoff) evaluation results for high-voltage transistors of semiconductor integrated circuit devices formed using a conventional selective oxidation process vs. a plasma oxidation process according to some embodiments of the present invention.

FIG. 5 is a graph illustrating tunnel gate leakage evaluation results for stacked cell gates of semiconductor integrated circuit devices formed using a conventional selective oxidation process vs. semiconductor integrated circuit devices formed according to some embodiments of the present invention;

FIG. 6 is a graph illustrating Idoff evaluation results for high-voltage transistors of semiconductor integrated circuit devices formed using a conventional selective oxidation process vs. semiconductor integrated circuit devices formed according to an embodiment of the present invention.

FIG. 7A is a graph illustrating hump characteristics for high-voltage transistors of semiconductor integrated circuit devices formed using a conventional selective oxidation process.

FIG. 7B is a graph illustrating hump characteristics for high-voltage transistors of semiconductor integrated circuit devices formed using a plasma oxidation process according to some embodiments of the present invention.

FIG. 7C is a graph illustrating hump characteristics for high-voltage transistors of semiconductor integrated circuit devices formed according to some embodiments of the present invention.

FIG. 8A is a graph illustrating cell distribution evaluation results for a semiconductor integrated circuit device formed using a conventional selective oxidation process.

FIG. 8B is a graph illustrating cell distribution evaluation results for a semiconductor integrated circuit device formed according to some embodiments of the present invention.

### DESCRIPTION OF EMBODIMENTS ACCORDING TO THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is tuned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

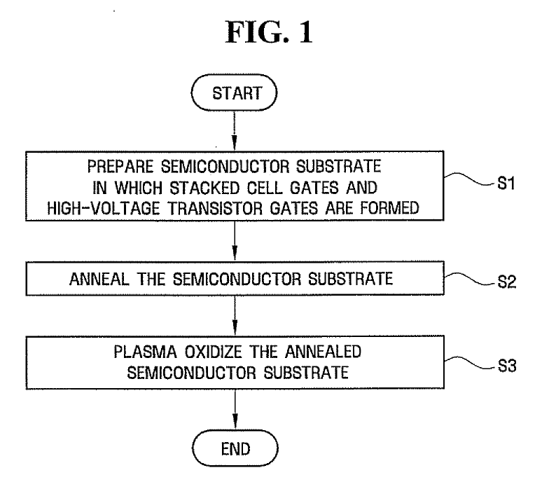

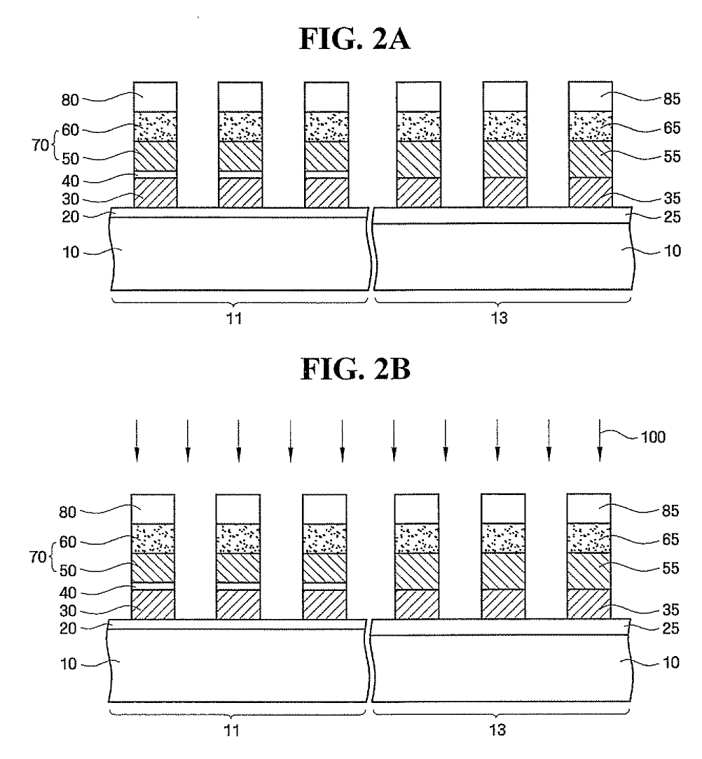

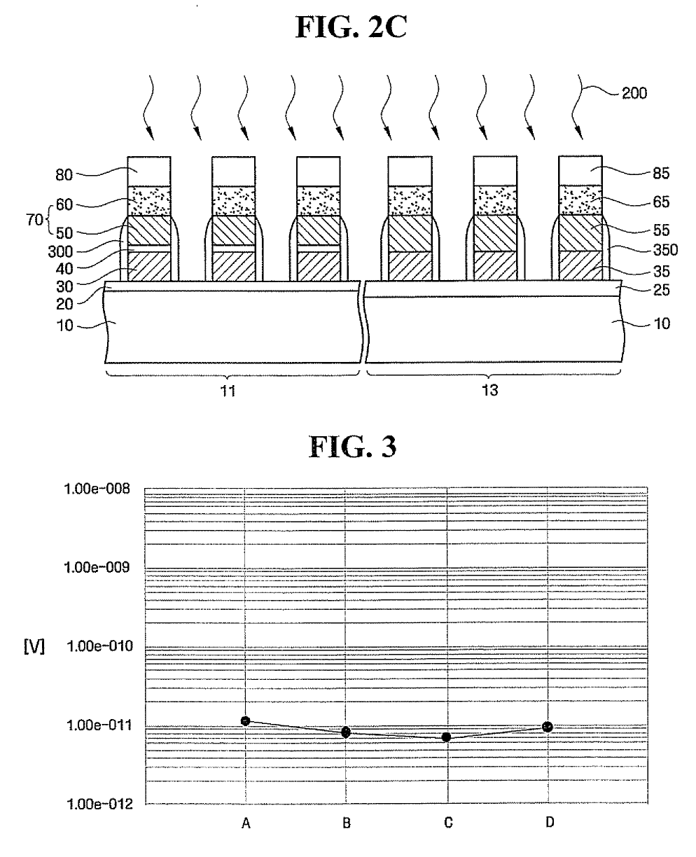

FIG. 1 is a flowchart diagram illustrating methods of forming semiconductor integrated circuit devices according to some embodiments of the present invention, and FIGS. 2A through 2C are sequential sectional views illustrating methods of forming semiconductor integrated circuit devices according to some embodiments of the present invention.

Referring to FIG. 1, first, a semiconductor substrate, in which a plurality of stacked cell gates are formed in a memory cell region and a plurality of high-voltage transistor gates are formed in a peripheral circuit region, is prepared (S1).

In some embodiments according to the invention, it is preferred that the stacked cell gates and the high-voltage transistor gates include a metal-containing layer such as a metal layer or a metal silicide layer. In the following description, a gate including a metal layer and a gate including a metal silicide layer are designated metal gate“and “silicide gate,” respectively.

In more detail, referring to FIG. 2A, each cell gate stack formed in a memory cell region 11 includes a floating gate 30, an inter-gate insulating layer 40, a control gate 70, and a gate mask layer 80 which are sequentially stacked on a gate oxide layer 20 covering a substrate 10 of the memory cell region 11.

In some embodiments according to the invention, the substrate 10 may be made of Si, Ge, SiGe, GaP, GaAs, SiC, SiGeC, InAs, and/or InP, but is not limited to the illustrated examples. Alternatively, an SOI substrate may also be used.

The gate oxide layer 20 formed on the substrate 10 may be in the shape of a single layer or multiple layer made of SiO₂, HfO, AlO, ZrO, TaO, HfSiOx, and/or HfSiOxNy, but is not limited thereto.

In addition, the floating gate 30 formed on the gate oxide layer 20 is responsible for charge or information storage by carrier trap. Tile floating gate 30 may be formed as a polysilicon film doped with impurity, but is not limited thereto. Like the above-described gate oxide layer 20, the inter-gate insulating layer 40 formed on the floating gate 30 to insulate the floating gate 30 and the control gate 70 may be in the shape of a single layer or multiple layer made of SiO₂, ONO, HfO, AlO, ZrO, TaO, HfSiOx, and/or HfSiOxNy, but is not limited thereto.

The control gate 70 is formed on the inter-gate insulating layer 40. The control gate 70 may be composed of a polysilicon layer 50 doped with impurity and a metal-containing layer 60. Here, the “metal-containing layer 60” is defined as a layer including a metal layer or a metal silicide layer. At this time, a barrier metal layer (not shown) may be further formed on a lower surface of the metal layer. Although not shown, the control gate 70 may also be formed as a metal-containing layer such as a metal layer/barrier metal layer or a metal silicide layer, without using a polysilicon layer.

In some embodiments according to the invention, the metal layer may be W, Ni, Co, TaN, Ru—Ta, TiN, Ni—Ti, Ti—Al—N, Zr, Hf, Ti, Ta, Mo, MoN, WN, Ta—Pt, Ta—Ti, and/or W—Ti, and the barrier metal layer may be WN, TiN, TaN, and/or TaCN, but the present invention is not limited to the illustrated examples. The metal silicide layer may be WSi, CoSix, and/or NiSix, but is not limited to the illustrated examples.

Since the process of patterning the stacked cell gate by stacking various material layers is performed by well known methods, a detailed explanation thereof will not be given and it is noted that the illustrated process is not intended to limit the invention in any way.

On the other hand, as shown in FIG. 2A, a plurality of high-voltage transistor gates are formed in a peripheral circuit region 13. In detail, each of the high-voltage transistor gates includes a lower conductive layer 35, an upper conductive layer 55, a metal-containing layer 55, and a gate mask layer 85 which are sequentially stacked on a gate oxide layer 25 covering a substrate 10 of the peripheral circuit region 13.

In some embodiments according to the invention, the layers constituting the high-voltage transistor gates may be made of the same materials as corresponding ones of the layers constituting the above-described stacked cell gates. In detail, the substrate 10 and the gate oxide layer 25 of the peripheral circuit region 13 may be made of the same materials as used for the substrate 10 and the gate oxide layer 20 of the memory cell region 11, and thus, a further detailed description thereof will be omitted.

In some embodiments according to the invention, the lower conductive layer 35, the upper conductive layer 55, the metal-containing layer 65, and the gate mask layer 85 constituting each high-voltage transistor gate may be respectively made of the same materials as used for the floating gate 30, the polysilicon layer 50, the metal-containing layer 60, and the gate mask layer 80 constituting each cell gate stack, and thus, a detailed description thereof will be omitted.

Since the process of forming the high-voltage transistor gates is performed by well known methods, like the stacked cell gate pattering process, a further detailed explanation thereof will not be given and it is noted that the illustrated process is not intended to limit the invention in any way.

As described above with reference to FIG. 1, the semiconductor substrate, in which the plurality of the stacked cell gates are formed in the memory cell region and the plurality of the high-voltage transistor gates are formed in the peripheral circuit region, is annealed (S2).

Referring to FIG. 2B, the substrate structure shown in FIG. 2A is subjected to an annealing process 100. As a result, damage (e.g., dangling bond) to the substrate structure by etching for gate patterning can be recovered. The recovered state of the substrate structure is not shown in FIG. 2B.

The annealing process 100 may be performed under hydrogen, nitrogen, or a mixed gas thereof. Another gas such as argon, together with hydrogen and/or nitrogen, may be further supplied, which is also within the scope of the present invention.

During the annealing process 100, an annealing chamber may be maintained at a temperature of about 400° C. to 1,000° C. Furthermore, the annealing process 100 may be appropriately continued for about 1 to about 180 minutes considering the reaction conditions such as the reaction temperature.

Referring again to FIG. 1, the annealed semiconductor substrate is subjected to a plasma oxidation process (S3). The plasma oxidation process can reduce bird's beak encroachment and punch-through phenomenon compared to a conventional reoxidation process. Furthermore, even when a metal layer is contained in a gate, selective reoxidation enabling antioxidation of the metal layer, and at the same time, recovery of etching damage, can be accomplished by appropriately adjusting the flow rate ratio of hydrogen and oxygen.

Referring to FIG. 2C, in some embodiments according to the invention, oxide films 300 and 350 are respectively formed at sidewalls of the floating gate 30 and the polysilicon layer 50 of each cell gate stack and at sidewalls of the lower conductive layer 35 and the upper conductive layer 55 of each high-voltage transistor gate during a plasma oxidation process with plasma irradiation indicated by arrows 200. Although not shown, an oxide film may also be formed at the gate oxide layers 20 and 25 to recover etching damage.

During the plasma oxidation process 200, in some embodiments according to the invention, a mixed gas of a hydrogen gas and an oxygen gas may be used as a plasma source. In this regard, when the stacked cell gates and the high--voltage transistor gates are metal gates, to perform selective oxidation for preventing the oxidation of a metal layer, H₂ and O₂ gas are supplied at a flow rate ratio(H₂/O₂) in a range of 0.5 to 16. On the other hand, in some embodiments according to the invention, in a case where the stacked cell gates and the high-voltage transistor gates are silicide gates, a H₂/O₂ gas flow rate ratio may be in a range of 0 to 16.

During the plasma oxidation process 200, an inert gas may be injected into a process chamber. The inert gas may be He, Ne, Ar, Kr, Rn, or a mixed gas, but is not limited to the illustrated examples. The flow rate of the inert gas may be about 0 to about 2,000 sccm.

The plasma oxidation process 200 may be performed at a temperature of room temperature to about 1,000° C. In addition, a chamber pressure may be adjusted to be in a range of about 1 m Torr to about 10 Torr. A level of power applied to the process chamber may range from about 100 W to about 3,400 W. The plasma oxidation process may be performed for about 60 to about 1,200 seconds.

In such a manner, the gate reoxidation process for manufacturing a semiconductor integrated circuit device may be completed. A semiconductor integrated circuit device can be completed by subsequent processes well known in the art, including forming a source/drain region, forming a spacer, and the like, although not shown.

Various characteristics of semiconductor integrated circuit devices manufactured according to an embodiment of the present invention were evaluated as follows and a detailed description thereof will now be provided with reference to FIGS. 3 through 8.

Semiconductor substrates which had the same gate structure but were manufactured by different reoxidation processes after gate patterning, were used as samples for characteristics evaluation. In detail, the samples used for characteristics evaluation had commonly the following semiconductor substrate structure.

A plurality of stacked cell gates were disposed in a memory cell region, each cell gate stack including a gate oxide layer made of SiO₂, a floating gate made of polysilicon, an ONO layer, a polysilicon layer, a barrier metal layer made of WN, a metal layer made of W, and a gate mask layer made of SiN which were sequentially stacked on a silicon substrate of the memory cell region. A peripheral circuit region had the same gate structure as the memory cell region but an ONO layer was omitted. That is, a plurality of high-voltage transistor gates were disposed in the peripheral circuit region, each high-voltage transistor gate including a gate oxide layer made of SiO₂, a lower conductive layer made of polysilicon, an upper conductive layer made of polysilicon, a barrier metal layer made of WN, a metal layer made of W, and a gate mask layer made of SiN which were sequentially stacked on a silicon substrate of the peripheral circuit region.

Referring to FIGS. 3 through 8, samples A through D are comparative samples with respect to samples of the present invention. As for the samples A and B, a conventional oxidation process was used as a reoxidation process. As for the samples C and D, only a plasma oxidation process was used as a reoxidation process.

On the other hand, samples E and F are test samples manufactured according to methods embodiments of the present invention including the following reoxidation process.

Semiconductor substrates as described above were annealed in an annealing chamber at a temperature of 900° C. under a hydrogen atmosphere for 30 minutes, Then, the annealed semiconductor substrates were subjected to plasma oxidation in a process chamber. At this time, the process conditions for the plasma oxidation was as follows: a H₂/O₂ gas flow rate ratio was 2, the flow rate of argon (Ar) used as an inert gas was 1,000 sccm, a process temperature was 400° C., a process pressure was 0.05 Torr, a power to be applied to the process chamber was 2,200 W, and process duration was 120 seconds.

The characteristics evaluation results for the test samples A through F are as follows.

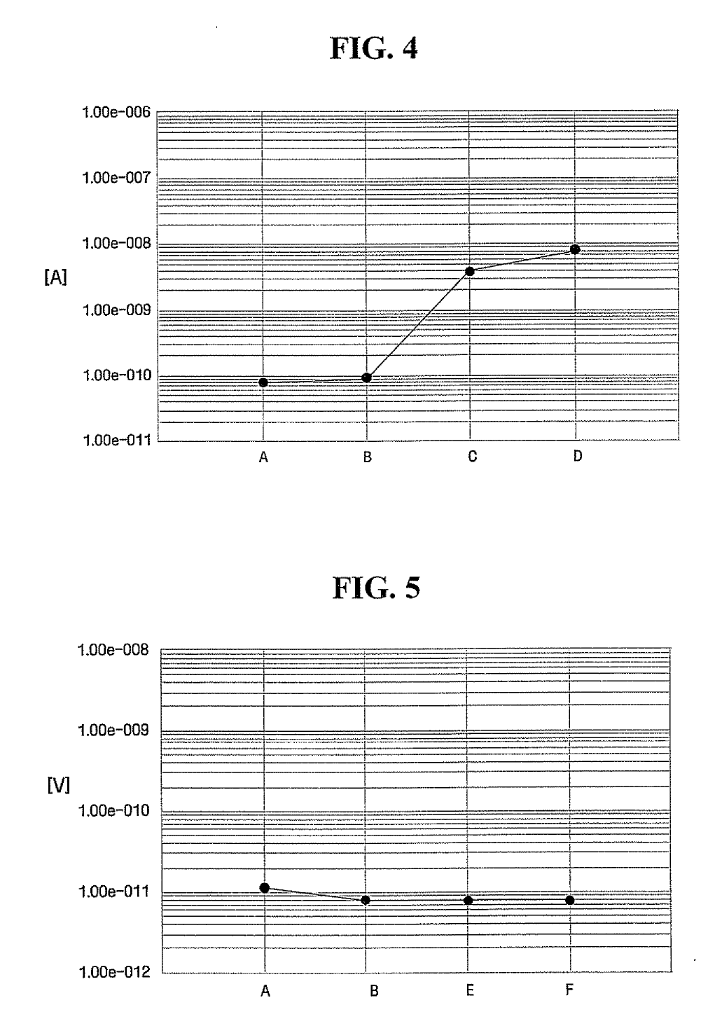

FIGS. 3 and 4 illustrate respectively tunnel gate leakage measurements of stacked cell gates and off-state drain leakage current (Idoff) measurements of high-voltage transistors for the samples A through D.

Referring to FIG. 3, the samples C and D manufactured using a plasma oxide process exhibited significantly reduced tunnel gate leakage levels of stacked cell gates compared to the samples A and B manufactured using a conventional selective oxidation process. However, referring to FIG. 4, the samples A and B exhibited considerably reduced Idoff values of high-voltage transistors compared to the samples C and D.

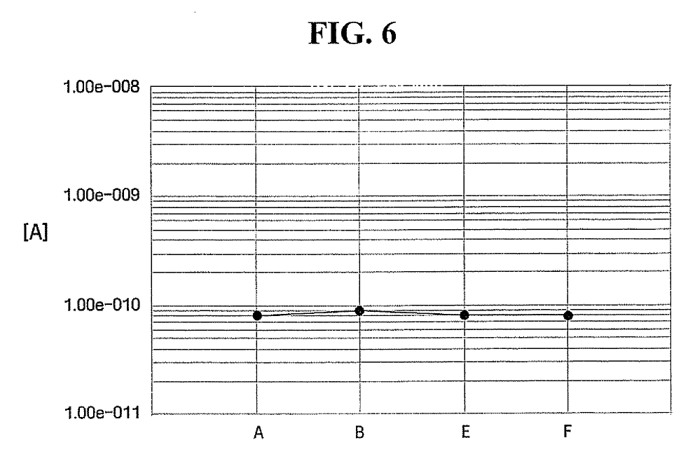

FIGS. 5 and 6 illustrate respectively tunnel gate leakage measurements of stacked cell gates and Idoff measurements of high-voltage transistors for the samples A, B, F, and F. Referring to FIGS. 5 and 6, the samples E and F manufactured according to the present invention exhibited better tunnel gate leakage and Idoff characteristics compared to the samples A and B. In particular, referring to FIGS. 4 and 6, the samples E and F manufactured using an annealing process and then a plasma oxidation process as a gate reoxidation process were greatly improved in Idoff characteristics of high-voltage transistors compared to the samples C and D manufactured using only a plasma oxidation process as a gate reoxidation process.

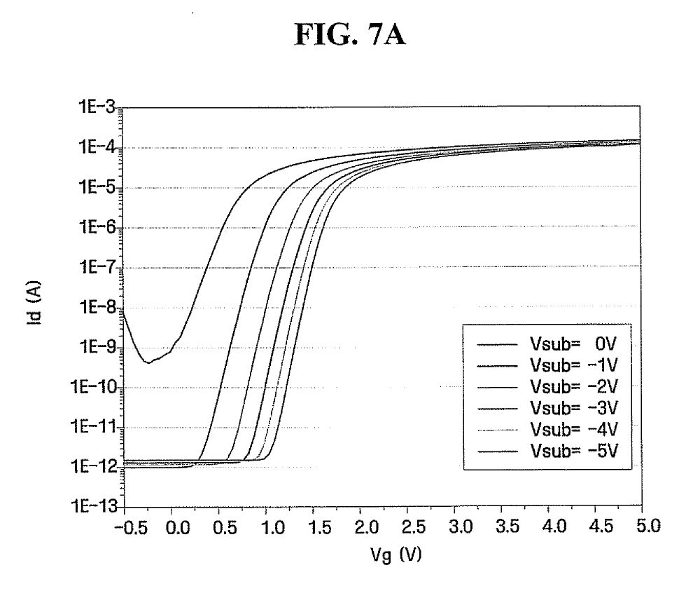

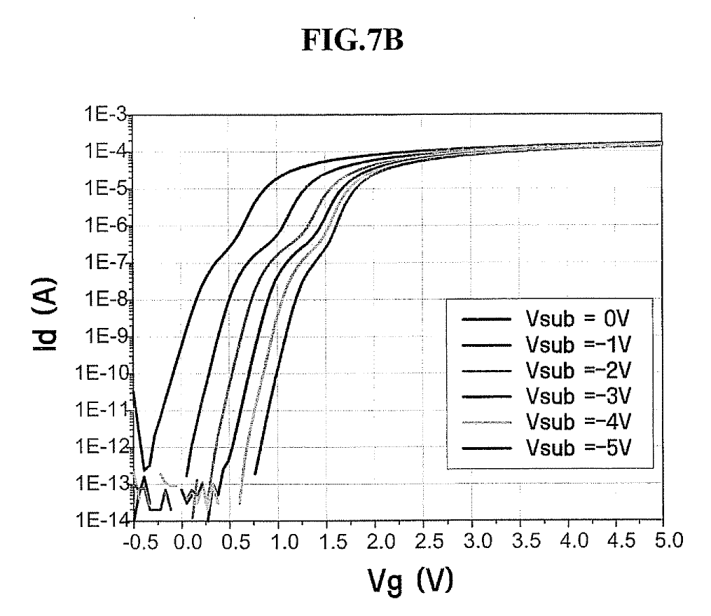

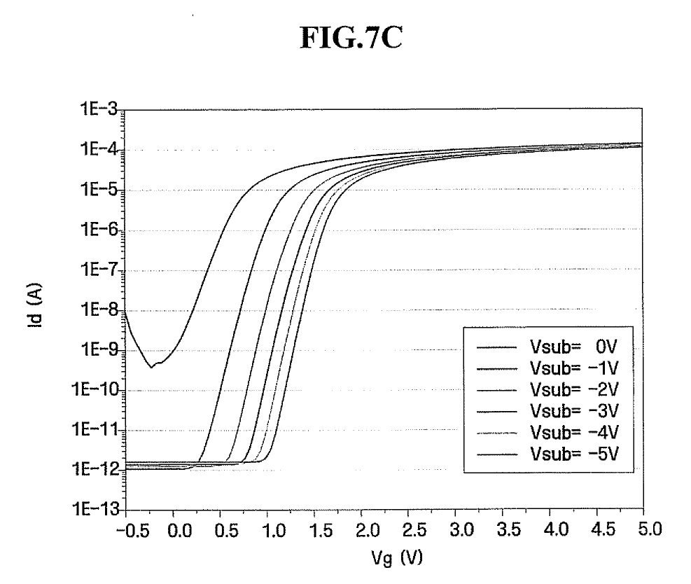

FIGS. 7A through 7C illustrate hump characteristics of high-voltage transistors of a peripheral circuit region for the samples A, C, and E, respectively. Referring to FIGS. 7A through 7C, a hump phenomenon appears in the sample C manufactured using only a plasma oxidation process as a gate reoxidation process, whereas no hump phenomenon is observed in the sample E manufactured using an annealing process and then a plasma oxidation process as a gate reoxidation process and the sample A manufactured using a selective oxidation process as a gate reoxidation process.

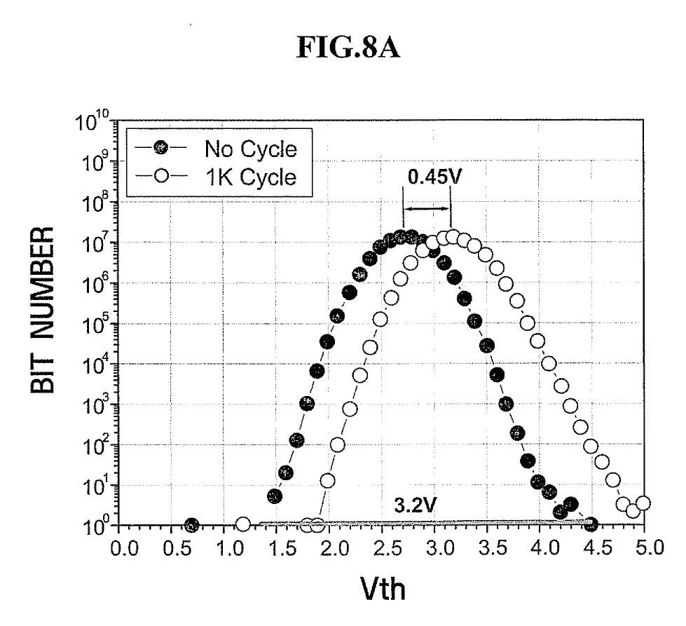

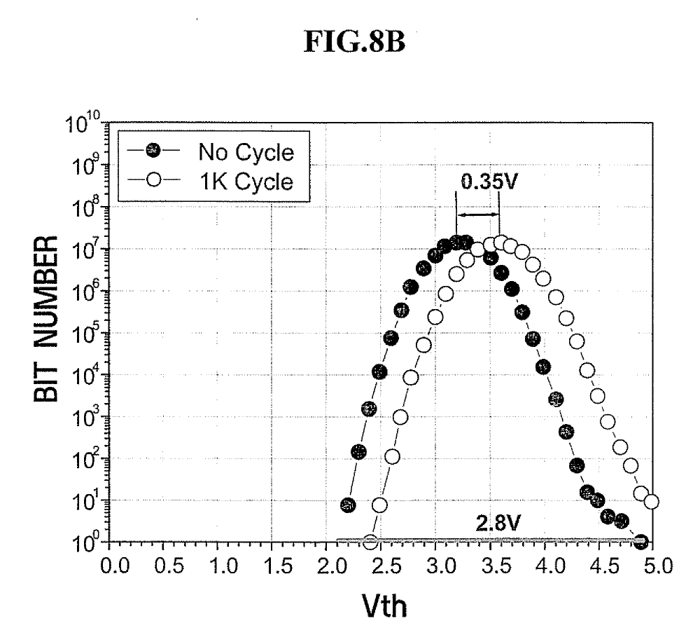

FIGS. 8A and 8B illustrate cell distribution evaluation results for the samples A and E. The cell distribution was evaluated by measuring the cell threshold voltage (Vth) distribution of each sample with no cycles and after 1K cycle of programming and erasing. Referring to FIGS. 8A and 8B, the cell distribution and Vth shift of the sample E manufactured according to the present invention were respectively 0.4 V and 0.1 V smaller than those of the sample A manufactured using a conventional selective oxidation process.

As apparent from the above description, according to methods of manufacturing a semiconductor integrated circuit device of the present invention, severe bird's beak encroachment and punch-through phenomena can be prevented and the hump phenomenon of high-voltage transistors can be minimized during gate formation. Accordingly, uniformity in the cell distribution may be improved, thereby attaining a semiconductor integrated circuit device with better reliability.

While the present invention has been particularly shown and described with reference to exemplary embodiments thereof, it will be understood by those of ordinary skill in the art that various changes in form and details may be made therein without departing from the spirit and scope of the present invention as defined by the following claims. Therefore, it is to be understood that the above-described embodiments have been provided only in a descriptive sense and will not be construed as placing any limitation on the scope of the invention.

What is claimed:

1. A method of forming an integrated circuit device, the method comprising:
forming a plurality of stacked cell gates in a memory cell region of a semiconductor substrate and a plurality of high-voltage transistor gates in a peripheral circuit region of the semiconductor substrate;
annealing the semiconductor substrate including both the plurality of stacked cell gates and the plurality of high-voltage transistor gates; and
plasma oxidizing the annealed semiconductor substrate including both the plurality of stacked cell gates and the plurality of high-voltage transistor gates.

2. A method according to claim 1, wherein the plurality of the stacked cell gates and the plurality of the high-voltage transistor gates each comprise a metal gate or a silicide gate.

3. A method according to claim 2, wherein the metal gate comprises a multi-layer structure including a metal layer/polysilicon layer, a metal layer/barrier metal layer, or a metal layer/barrier metal layer/polysilicon layer.

4. A method according to claim 3, wherein the metal layer comprises W, Ni, Co, TaN, Ru—Ta, TiN, Ni—Ti, Ti—Al—N, Zr, Hf, Ti, Ta, Mo, MoN, WN, Ta—Pt, Ta—Ti, and/or W—Ti.

5. A method according to claim 3, wherein the barrier metal layer comprises WN, TiN, TaN, and/or TaCN.

6. A method according to claim 2, wherein the silicide gate comprises a silicide layer or a multi-layer structure of silicide layer/polysilicon layer.

7. A method according to claim 6, wherein the silicide layer comprises WSi, CoSix, and NiSix.

8. A method according to claim 1, wherein the plurality of the stacked cell gates and the plurality of the high-voltage transistor gates each include a gate oxide layer comprising SiO₂, HfO, AlO, ZrO, TaO, HfSiOx, and/or HfSiOxNy.

9. A method according to claim 1, wherein an inter-gate insulating layer is between a floating gate and a control gate of each of the plurality of the stacked cell gates, and comprises SiO₂, ONO, HfO, AlO, ZrO, TaO, HfSiOx, and/or HfSiOxNy.

10. A method according to claim 1, wherein annealing the semiconductor substrate is performed under a hydrogen atmosphere.

11. A method according to claim 1, wherein the annealing the semiconductor substrate is performed at a temperature of about 400° C. to about 1,000° C.

12. A method according to claim 1, wherein annealing the semiconductor substrate is performed for about 1 to about 180 minutes.

13. A method according to claim 1, wherein plasma oxidizing the annealed semiconductor substrate further comprises supplying a mixed gas of a hydrogen gas and an oxygen gas as a plasma source into a process chamber.

14. A method according to claim 13, wherein when the plurality of the stacked cell gates and the plurality of the high-voltage transistor gates each comprise a metal gate, wherein a flow rate ratio of the hydrogen gas and the oxygen gas (H₂/O₂) is about 0.5 to about 16.

15. A method according to claim 13, wherein when the plurality of the stacked cell gates and the plurality of the high-voltage transistor gates each comprise a silicide gate, wherein a flow rate ratio of the hydrogen gas and the oxygen gas (H₂/O₂) is about 0 to about 16.

16. A method according to claim 13, plasma oxidizing the annealed semiconductor substrate further comprises providing an inert gas comprising He, Ne, Ar, Kr, and/or Rn to the process chamber.

17. A method according to claim 1, wherein plasma oxidizing the annealed semiconductor substrate is performed at a temperature of about room temperature to about 1,000° C.

18. A method according to claim 1, wherein plasma oxidizing the annealed semiconductor substrate is performed under a pressure of about 1 mTorr to about 10 Torr.

19. A method according to claim 1, wherein plasma oxidizing the annealed semiconductor substrate is performed at a power level of about 100W to about 3,400 W.

20. A method according to claim 1, wherein the plasma oxidizing of the semiconductor substrate is performed for about 60 to about 1200 seconds.

21. A method of forming an integrated circuit device, the method comprising:
annealing a substrate including both a plurality of stacked cell gates and a plurality of high-voltage transistor gates; and then
oxidizing the annealed semiconductor substrate using a plasma including H₂ gas and O₂ gas provided at a flow rate ratio (H₂ to O₂) of about 0 to about 16.

22. A method according to claim 21 wherein if the stacked cell gates include a first metal layer and the high-voltage transistor gates include a second metal layer, the flow rate ratio (H₂ to O₂) comprises about 0 to about 16; and
wherein if the stacked cell gates include a first silicide layer and the high-voltage transistor gates include a second silicide layer the flow rate ratio (H₂ to O₂) comprises about 0.5 to about 16.

23. A method of forming an integrated circuit device, the method comprising:
annealing a substrate including both stacked cell gates of a memory and high-voltage transistor gates both including either metal or silicide containing layers; and then
re-oxidizing portions of the substrate having both the stacked cell gates and the high-voltage transistor gates in a plasma process including H₂ and O₂.
